(19) United States
(12) Patent Application Publication
(10) Pub. No.: US 2025/0169187 A1
(43) Pub. Date: May 22, 2025

(54) SEMICONDUCTOR DEVICES

(71) Applicant: Samsung Electronics Co., Ltd., Suwon-si (KR)

(72) Inventors: Jongsoon PARK, Suwon-si (KR); Gunpil HWANG, Suwon-si (KR); Hyonwook RA, Suwon-si (KR); Keunhee BAI, Suwon-si (KR); Jinwook LEE, Suwon-si (KR); Sangho CHEON, Suwon-si (KR)

(73) Assignee: Samsung Electronics Co., Ltd., Suwon-si (KR)

(21) Appl. No.: 18/753,484

(22) Filed: Jun. 25, 2024

(30) Foreign Application Priority Data
Nov. 22, 2023 (KR) 10-2023-0162897

(51) Int. Cl. H01L 27/02; H01L 27/088; H01L 29/06; H01L 29/08; H01L 29/423; H01L 29/775; H01L 29/78; H01L 29/786

(52) U.S. Cl. CPC H10D 89/10; H10D 30/43; H10D 30/62; H10D 30/6713; H10D 30/6735; H10D 30/6757; H10D 62/121; H10D 62/151; H10D 84/834

(57) ABSTRACT

A semiconductor device may include a device isolation layer on a substrate and defining active regions extending a first direction; gate structures intersecting the active regions and extending in a second direction; channel layers spaced apart from each other on the active regions and surrounded by the gate structures; and source/drain regions connected to the channel layers and in recessed regions of the active regions on both sides of the gate structures. First and second regions of the substrate respectively may be spaced apart by a first length and the second length from first ends of the gate structures in the second direction. The second length may be longer than the first length. An upper surface of the device isolation layer may have recessed portion on the first region of the substrate and a flat upper surface on the second region of the substrate.

### CROSS-REFERENCE TO RELATED APPLICATION(S)

This application claims benefit of priority to Korean Patent Application No. 10-2023-0162897 filed on Nov. 22, 2023, in the Korean Intellectual Property Office, the disclosure of which is incorporated herein by reference in its entirety.

### BACKGROUND

The present disclosure relates to semiconductor devices.

With an increase in demands for high performance, high speed, and/or multifunctionalization of semiconductor devices, the degree of integration of semiconductor devices is increasing. Accordingly, a line width of patterns and a gap therebetween are gradually becoming finer, and the introduction of photolithography processes using shorter wavelengths, such as extreme ultraviolet (EUV) is gradually increasing. In addition, efforts are being made to develop semiconductor devices with channels having a three-dimensional structure in order to overcome the limitations of operating characteristics due to the reduction in the size of a planar oxide semiconductor (MOSFET).

### SUMMARY

An aspect of the present disclosure provides a semiconductor device having improved integration and improved electrical characteristics.

According to an embodiment of the present disclosure, a semiconductor device may include a substrate including active regions extending in a first direction; a device isolation layer on the substrate and defining the active regions; gate structures on the substrate, the gate structures intersecting the active regions and extending in a second direction; a plurality of channel layers on the active regions and surrounded by the gate structures, the plurality of channel layers being spaced apart from each other in a third direction, the third direction perpendicular to an upper surface of the substrate; and source/drain regions in recessed regions of the active regions on both sides of the gate structures, the source/drain regions being connected to the plurality of channel layers. A first region of the substrate may be spaced apart from first ends of the gate structures in the second direction by a first length in the second direction. A second region of the substrate may be spaced apart from the first ends of the gate structures by a second length in the second direction. The second length may be longer than the first length. An upper surface of the device isolation layer on the first region of the substrate may have recessed portions. The device isolation layer on the second region of the substrate may have a flat upper surface.

According to an embodiment of the present disclosure, a semiconductor device may include a substrate including an active region extending in a first direction; a device isolation layer defining the active region on the substrate; a gate structure on the substrate, the gate structure extending in a second direction and intersecting the active region; and a source/drain region on at least one side of the gate structure. A first region of the substrate and a second region of the substrate may be sequentially disposed in the second direction from a first end of the gate structure in the second direction. An upper surface of the device isolation layer on the first region may have a protrusion corresponding to the gate structure, and the device isolation layer on the second region may have a flat upper surface.

According to an embodiment of the present disclosure, a semiconductor device may include a substrate including active regions extending in a first direction; a device isolation layer on the substrate and defining the active regions; gate structures on the substrate, the gate structures intersecting the active regions and extending in a second direction; a plurality of channel layers on the active regions and surrounded by the gate structure, the plurality of channel layer being spaced apart from each other in a third direction, the third direction perpendicular to an upper surface of the substrate; and source/drain regions in recessed regions of the active regions at both sides of the gate structures, and the source/drain regions being connected to the plurality of channel layers. Among the active regions, an upper surface of an active region closest to ends of the gate structures in the second direction may have a step portion between the gate structures.

A semiconductor device having improved integration and improve electrical characteristics may be provided by improving line edge roughness (LER) and line width roughness (LWR) of a line pattern using an ion beam etching process.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to example embodiments;

FIGS. 2A and 2B are cross-sectional views illustrating a semiconductor device according to example embodiments;

FIG. 3 is a plan view illustrating a semiconductor device according to example embodiments;

FIG. 4 is a cross-sectional view illustrating a semiconductor device according to example embodiments;

FIGS. 5A and 5B are a plan view and a cross-sectional view illustrating a semiconductor device according to example embodiments;

FIG. 6 is a cross-sectional view illustrating a semiconductor device according to example embodiments;

FIG. 7 is a plan view illustrating a semiconductor device according to example embodiments;

FIGS. 8A to 17B are views illustrating a method of manufacturing a semiconductor device according to example embodiments according to a process sequence; and

FIGS. 18A, 18B, and 19 are views illustrating some processes of a method of manufacturing a semiconductor device according to example embodiments.

### DETAILED DESCRIPTION

Hereinafter, example embodiments of the present disclosure will be described with reference to the accompanying drawings.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments of the present disclosure will be described with reference to the accompanying drawings. Hereinafter, it may be understood that the expressions such as “on,” “above,” “upper,” “below”, “beneath,” “lower,” and “side,” merely indicated based on drawings, except that they are indicated by drawings and referred to separately.

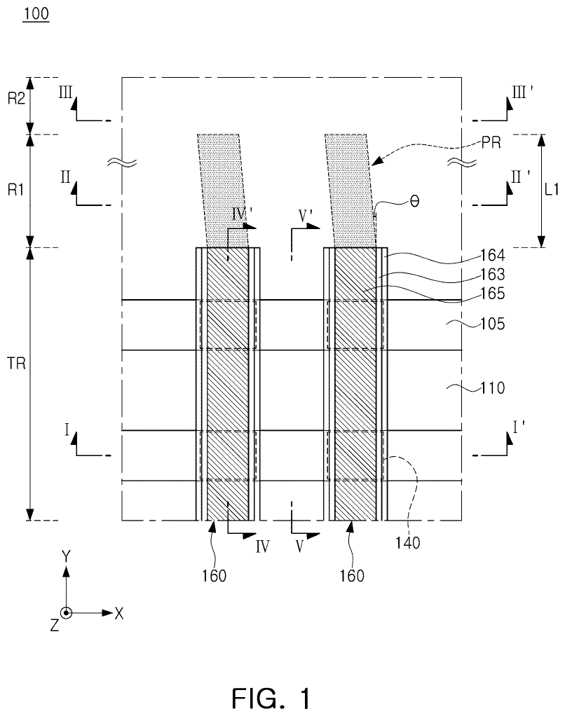

FIG. 1 is a plan view illustrating a semiconductor device according to example embodiments.

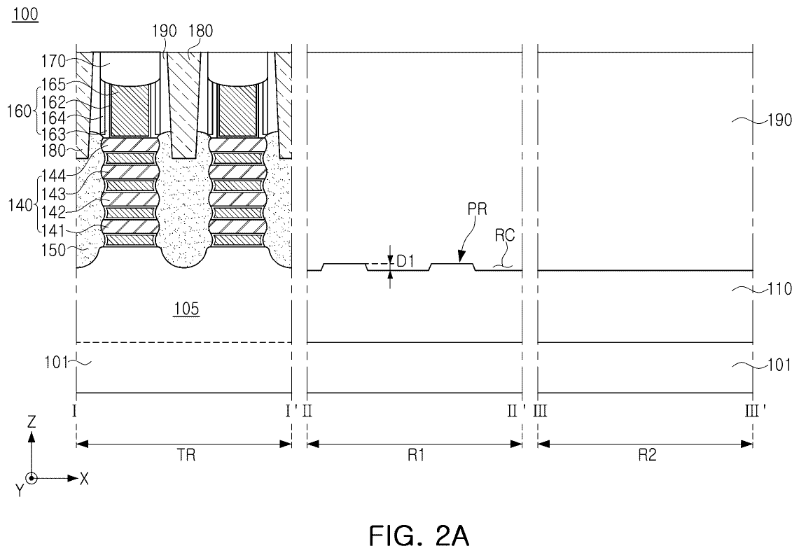

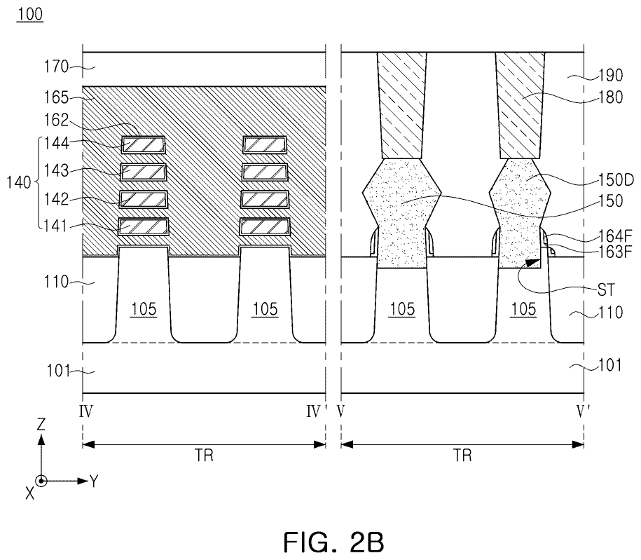

FIGS. 2A and 2B are cross-sectional views illustrating a semiconductor device according to example embodiments. FIG. 2A illustrates cross-sections taken along cutting lines I-I′, II-II′ and III-III′ of the semiconductor device of FIG. 1, and FIG. 2B illustrates cross-sections taken along the cutting lines IV-IV′ and V-V′ of the semiconductor device of FIG. 1. For convenience of description, only some components of a semiconductor device are illustrated in FIG. 1.

Referring to FIGS. 1 to 2B, a semiconductor device 100 may include a substrate 101 including a device region TR, a first region R1, and a second region R2, active regions 105 on the substrate 101, channel structures 140 including first to fourth channel layers 141, 142, 143 and 144 disposed to be vertically spaced from each other on the active regions 105, gate structures 160 extending by intersecting the active regions 105 and respectively including a gate electrode 165, source/drain regions 150 in contact with the channel structures 140, and contact plugs 180 connected to the source/drain regions 150. The semiconductor device 100 may further include a device isolation layer 110, a dummy source/drain region 150D, first and second fin spacer layers 163F and 164F, gate capping layers 170, and an interlayer insulating layer 190.

In the semiconductor device 100, the active region 105 may have a fin structure, and the gate electrode 165 may be disposed between the active region 105 and the channel structure 140 and between the first to fourth channel layers 141, 142, 143 and 144 of the channel structure 140, and may be disposed on the channel structure 140. Accordingly, the semiconductor device 100 may include transistors having a Multi Bridge Channel FET (MBCFET™) structure, which is a gate-all-around type field effect transistor.

The substrate 101 may have an upper surface extending in an X-direction and a Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include the device region TR, the first region R1, and the second region R2. The device region TR is a region in which the active regions 105 and the gate structures 160 are disposed, and may be a region in which a device such as a transistor is disposed. The first region R1 and the second region R2 are regions in which at least the gate structures 160 are not disposed, and may be a peripheral region of the device region TR. However, depending on a description method, the device region TR, first region R1 and second region R2 may be referred to as regions of the semiconductor device 100.

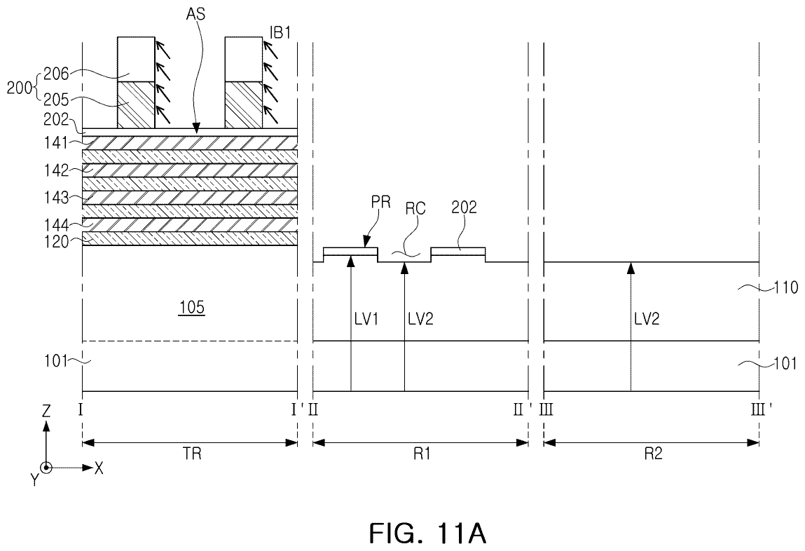

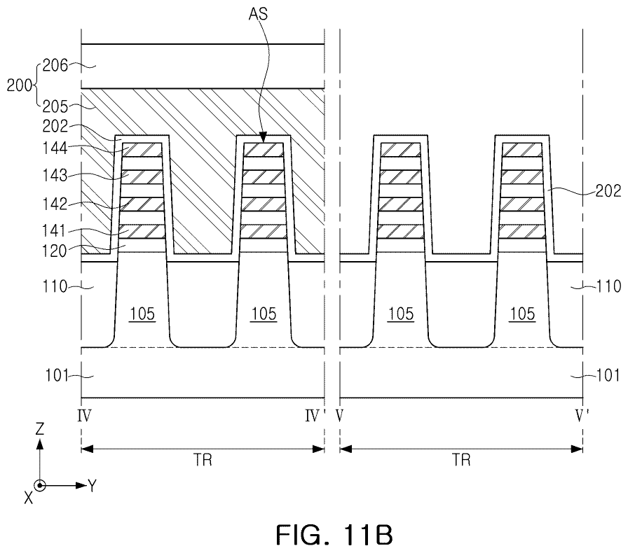

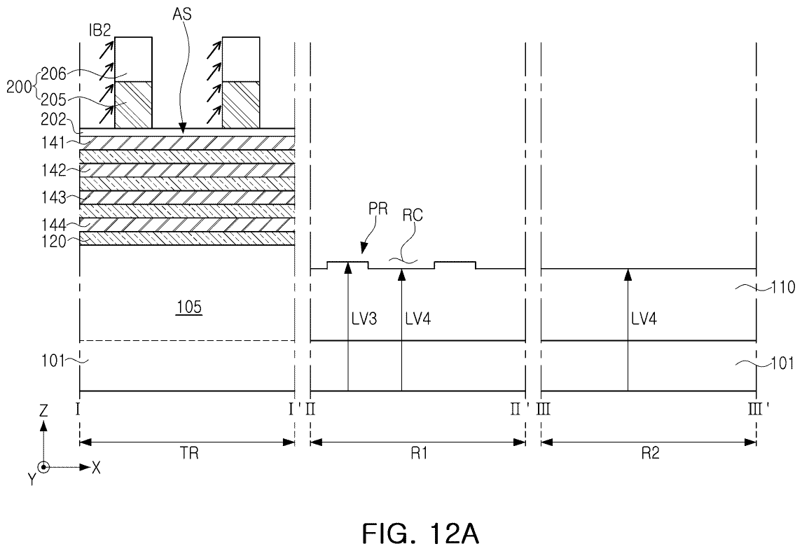

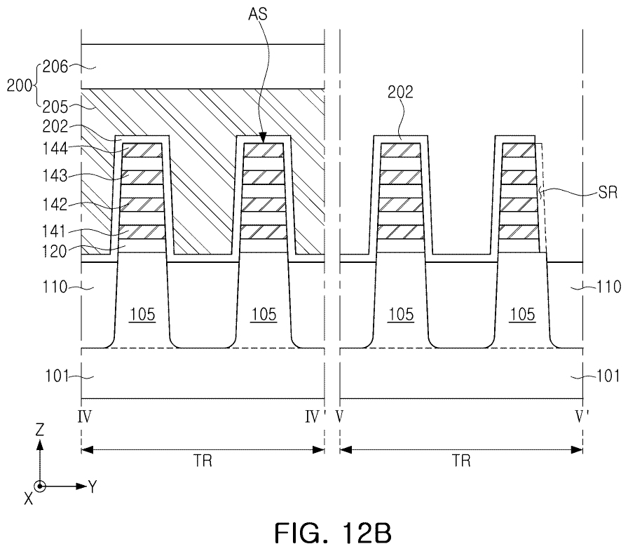

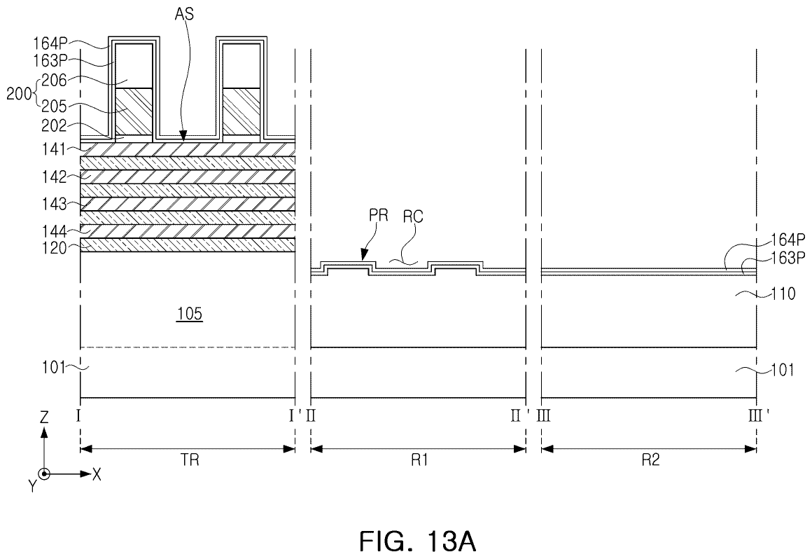

In this example embodiment, the first region R1 is a region adjacent to the gate structures 160 in an extending direction of the gate structures 160, for example, the Y-direction, and the second region R2 may be a region spaced apart from the device region TR. The first region R1 may be interposed between the second region R2 and the device region TR. The first region R1 may be a region up to a first length L1 from one end of the gate structures 160, and the second region R2 may be a region farther than the first length L1 from one end of the gate structures 160. For example, the first length L1 may range from about 800 nm to about 2000 nm, but the present disclosure is not limited thereto. The first length L1 will be described in more detail below with reference to FIGS. 11A to 12B. The first region R1 illustrated in FIG. 2A corresponds to a region spaced apart by a first distance from one end of the gate structures 160, and the second region R2 illustrated in FIG. 2A may correspond to a region spaced apart by a second distance that is longer than the first distance from one end of the gate structures 160.

The active regions 105 may be disposed on the substrate 101 and may be disposed to extend in a first direction, for example, the X-direction. The active regions 105 may be defined by a device isolation layer 110 formed by partially removing the substrate 101. However, depending on a description method, it may be possible to explain the active regions 105 as a portion of the substrate 101. The active regions 105 may partially protrude onto the device isolation layer 110, so that upper surfaces of the active regions 105 may be disposed on a higher level than an upper surface of the device isolation layer 110. The active regions 105 may be formed as a portion of the substrate 101, and may include an epitaxial layer grown from substrate 101. However, on both sides of the gate structure 160, the active regions 105 may be partially recessed to form recessed regions, and the source/drain regions 150 may be disposed in the recessed regions. In example embodiments, the active regions 105 may or may not include a well region including impurities. For example, the well region may be disposed at a desired and/or alternatively predetermined depth from the upper surface of the active regions 105.

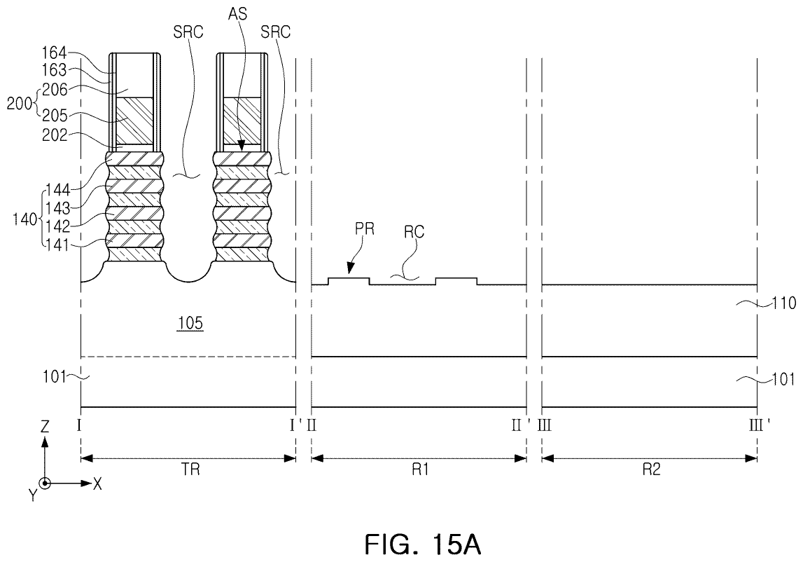

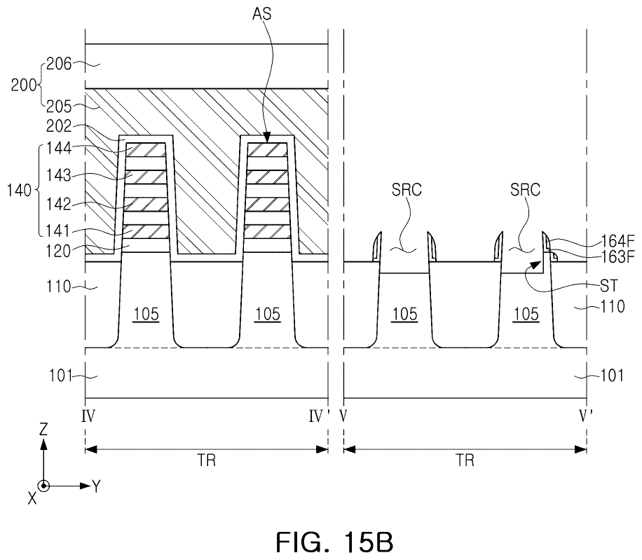

An outermost active region 105 closest to the first region R1 may have a shape different from the other active regions 105. The outermost active region 105 may be an active region 105 closest to ends of the gate structures 160. As illustrated in FIG. 2B, the active region 105 closest to the first region R1 may have a step portion ST on an upper surface thereof, between the gate structures 160. The active region 105 may have a protruding region on the upper surface thereof due to the step portion ST. The protruding region may be a region that remains without being recessed in a process described below with reference to FIGS. 15A and 15B. The upper surface of the active region 105 may include an inner region disposed on a low level and an end region disposed on a high level, according to the step portion ST. The end region may be closer to the first region R1 than the inner region.

The device isolation layer 110 may define active regions 105 on the substrate 101. The device isolation layer 110 may be formed by partially removing the substrate 101 through, for example, a shallow trench isolation (STI) process. The device isolation layer 110 may expose the upper surfaces of the active regions 105 and may partially expose upper portions of the active regions 105. In some example embodiments, the device isolation layer 110 may have a curved upper surface to have a higher level towards the active regions 105. The device isolation layer 110 may be formed of an insulating material. The device isolation layer 110 may be, for example, oxide, nitride, or a combination thereof.

In the first region R1, the device isolation layer 110 may have recessed portions RC and protrusions PR on an upper surface thereof. Accordingly, the device isolation layer 110 may have a curved upper surface having a step structure and the upper surface may be disposed on at least two levels. The protrusions PR may extend from at least a portion of the gate structures 160, respectively, for example, from an end of the gate electrode 165 and an end of the gate dielectric layer 162. The number of protrusions PR may be identical to the number of gate structures 160. The protrusions PR may be disposed to correspond to each of the gate structures 160. Accordingly, a curve of the upper surface of the device isolation layer 110 may have a shape corresponding to the gate structures 160.

As illustrated in FIG. 1, the protrusions PR may extend from the ends of the gate electrodes 165 in a direction inclined at a desired and/or alternatively predetermined angle θ from the Y-direction, which is an extension direction of the gate structures 160. The angle θ may range from about 0 degrees(°) to about 8 degrees. For example, the angle θ may be about 5 degrees. Accordingly, the protrusions PR may be disposed in a region shifted in the X-direction from an extension line of the gate structures 160, and a shifted length may increase in proportion to a distance from the gate structures 160.

The recessed portions RC may be disposed between the protrusions PR. A recessed depth D1 of the recessed portions RC may range, for example, from about 5 nm to about 10 nm, but may be variously changed in various example embodiments.

In the second region R2, the device isolation layer 110 may have a substantially flat upper surface without any recessed portion or protrusions. A level of the upper surface of the device isolation layer 110 in the second region R2 may be substantially identical to a level of the upper surface of the device isolation layer 110 in the recessed portions RC of the first region R1. The level of the upper surface of the device isolation layer 110 in the second region R2 may be lower than a level of an uppermost surface of the device isolation layer 110 in the first region R1, that is, a level of the protrusions PR.

The gate structures 160 may be disposed to extend in a second direction, for example, the Y-direction by intersecting the active regions 105 and the channel structures 140 on the active regions 105 and the channel structures 140. In the active regions 105 and/or the channel structures 140 intersecting the gate electrodes 165 of the gate structures 160, a functional channel region for transistors may be formed. Each of the gate structures 160 may include a gate electrode 165, gate dielectric layers 162 between the gate electrode 165 and the first to fourth channel layers 141, 142, 143 and 144, and first and second gate spacer layers 163 and 164 on side surfaces of the gate electrode 165.

The gate dielectric layer 162 may be disposed between the active region 105 and the gate electrode 165 and between the channel structure 140 and the gate electrode 165, and may be disposed to cover at least some of surfaces of the gate electrode 165. For example, the gate dielectric layer 162 may be disposed to surround all surfaces of the gate electrode 165 except an uppermost surface thereof. The gate dielectric layer 162 may extend between the gate electrode 165 and the first gate spacer layer 163, but the present disclosure is not limited thereto. The gate dielectric layer 162 may include oxide, nitride, or a high-κ material. The high-κ material may refer to a dielectric material having a higher dielectric constant than a silicon oxide film (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSixOy), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to example embodiments, the gate dielectric layer 162 may be formed of a multilayer film.

The gate electrode 165 may be disposed to fill a space between the first to fourth channel layers 141, 142, 143 and 144 on the active region 105 and extend onto the channel structure 140. The gate electrode 165 may be spaced apart from the first to fourth channel layers 141, 142, 143 and 144 by the gate dielectric layer 162. The gate electrode 165 may include a conductive material, and may include, for example, a metal nitride such as titanium nitride (TiN), tantalum nitride (TaN) or tungsten nitride (WN), and/or a metal material such as aluminum (Al), tungsten (W) or molybdenum (Mo), or a semiconductor material such as doped polysilicon. According to example embodiments, the gate electrode 165 may be comprised of two or more multiple layers.

The first and second gate spacer layers 163 and 164 may be disposed on both side surfaces of the gate electrode 165 on the channel structure 140. The first and second gate spacer layers 163 and 164 may insulate the source/drain regions 150 and the gate electrode 165. The first gate spacer layer 163 may be disposed on the gate dielectric layer 162 and may have an L-shape. The second gate spacer layer 164 may be disposed on the first gate spacer layer 163. However, in some example embodiments, the first and second gate spacer layers 163 and 164 may be formed of a single layer or may be formed of three or more layers. The first and second gate spacer layers 163 and 164 may be formed of at least one of oxide, nitride, and oxynitride, and may be formed of, for example, a low dielectric constant film. For example, the first gate spacer layer 163 includes SiOCN, and the second gate spacer layer 164 may include silicon oxide.

The first and second fin spacer layers 163F and 164F may be disposed on side surfaces of the source/drain regions 150 outside gate structures 160. The first and second fin spacer layers 163F and 164F may also remain on a side surface of the active region 105 connected to the dummy source/drain region 150D. However, the shape of the first and second fin spacer layers 163F and 164F disposed adjacently to the dummy source/drain region 150D is not limited to the shape illustrated in FIG. 2B, and may be variously changed in example embodiments.

The channel structures 140 may be disposed on the active regions 105, in regions in which the active regions 105 intersect the gate structures 160. Each of the channel structures 140 may include first to fourth channel layers 141, 142, 143 and 144, which are a plurality of channel layers disposed to be spaced apart from each other in the Z-direction. The first to fourth channel layers 141, 142, 143 and 144 may be sequentially disposed from the bottom. The channel structures 140 may be connected to the source/drain regions 150. The channel structures 140 may have a width equal to or similar to that of the gate structures 160 in the X-direction, and may have a width equal to or smaller than that of the active region 105 in the Y-direction. In a cross-section in the Y-direction, a channel layer disposed on the bottom, among the first to fourth channel layers 141, 142, 143 and 144, may have a width equal to or greater than that of a channel layer disposed on the top. The number and shape of channel layers forming one channel structure 140 may be variously changed in example embodiments. For example, one channel structure 140 may include three channel layers, and may include two channel layers or may include five or more channel layers.

The channel structures 140 may be formed of a semiconductor material, and may include, for example, at least one of silicon (Si), silicon germanium (SiGe), and germanium (Ge). For example, the channel structures 140 may be formed of the same material as the active regions 105. In some example embodiments, the channel structures 140 may include an impurity region disposed adjacently to the source/drain regions 150.

The source/drain regions 150 may be disposed in recessed regions that partially recess the upper portions of the active regions 105 on both sides of the gate structures 160. The recessed regions may extend along side surfaces of the channel structures 140 and sides surface of the gate dielectric layers 162. The source/drain regions 150 may be disposed to cover side surfaces of each of the first to fourth channel layers 141, 142, 143 and 144 of the channel structures 140 in the X-direction. Upper surfaces of the source/drain regions 150 may be disposed on a level equal to or higher than that of lower surfaces of the gate electrodes 165 on the channel structures 140, and the level may be variously changed in example embodiments. Side surfaces of the source/drain regions 150 may be curved according to the first to fourth channel layers 141, 142, 143 and 144 and the gate structure 160. However, specific shapes of the side surfaces of the source/drain regions 150 may be variously changed in example embodiments. In some example embodiments, the semiconductor device 100 may further include internal spacer layers disposed in parallel with the gate electrode 165, between the first to fourth channel layers 141, 142, 143, and 144 in the Z-direction.

The source/drain regions 150 may include at least one of a semiconductor material, for example, silicon (Si) and germanium (Ge), and may further include dopants. The source/drain regions 150 may be formed of an epitaxial layer.

On the active region 105 closest to the first region R1, the dummy source/drain region 150D may have a different shape from those on the other active regions 105 and is therefore referred to as a dummy source/drain region 150D. As illustrated in FIG. 2B, the dummy source/drain region 150D may be disposed on the step portion ST on the upper surface of the active region 105, and may have a relatively narrow width in the Y-direction. For example, the dummy source/drain region 150D may not actually form a transistor, but the present disclosure is not limited thereto. The dummy source/drain region 150D may be referred to as a dummy source/drain structure.

The gate capping layers 170 may be respectively disposed on the gate structures 160. The interlayer insulating layer 190 may be disposed to cover the source/drain regions 150 and the gate structure 160, and to cover the device isolation layer 110. Each of the gate capping layers 170 and the interlayer insulating layer 190 may include at least one of oxide, nitride, and oxynitride. According to example embodiments, the interlayer insulating layer 190 may include a plurality of insulating layers.

The contact plugs 180 may penetrate through the interlayer insulating layer 190 and be connected to the source/drain regions 150 and may apply an electrical signal to the source/drain regions 150. The contact plugs 180 may have inclined side surfaces in which a width of a lower portion thereof is narrower than a width of an upper portion thereof depending on an aspect ratio, but the present disclosure is not limited thereto. The contact plugs 180 may extend from the top, for example, below a lower surface of an uppermost fourth channel layer 144 of the channel structure 140, but the present disclosure is not limited thereto.

Each of the contact plugs 180 may include a metal silicide layer disposed in a lower end including a lower surface, and may further include a barrier layer forming side surfaces of the contact plug 180 and extending onto an upper surface of the metal silicide layer. For example, the barrier layer may include a metal nitride such as titanium nitride (TiN), tantalum nitride (TaN), or tungsten nitride (WN). The contact plugs 180 may include a metal material such as aluminum (Al), tungsten (W), or molybdenum (Mo). In example embodiments, the number and arrangement of conductive layers forming the contact plugs 180 may be variously changed.

An interconnection structure such as a contact plug may also be further disposed on the gate electrodes 165, and an interconnection structure connected to the contact plugs 180 may be further disposed on the contact plugs 180.

In the description of the following example embodiments, descriptions that overlap those described above with reference to FIGS. 1 to 2B will be omitted.

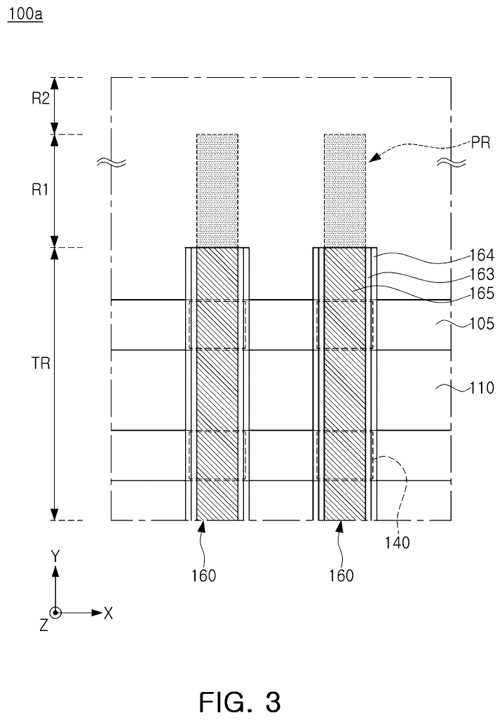

FIG. 3 is a plan view illustrating a semiconductor device according to example embodiments.

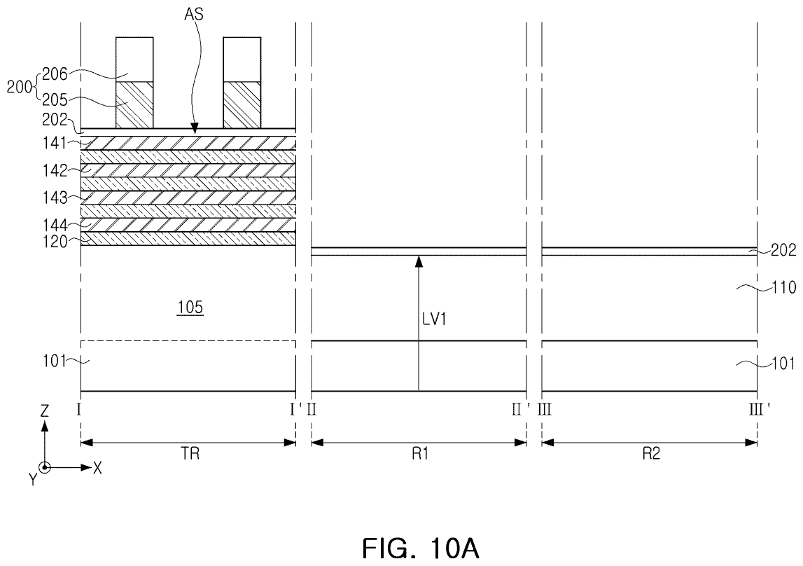

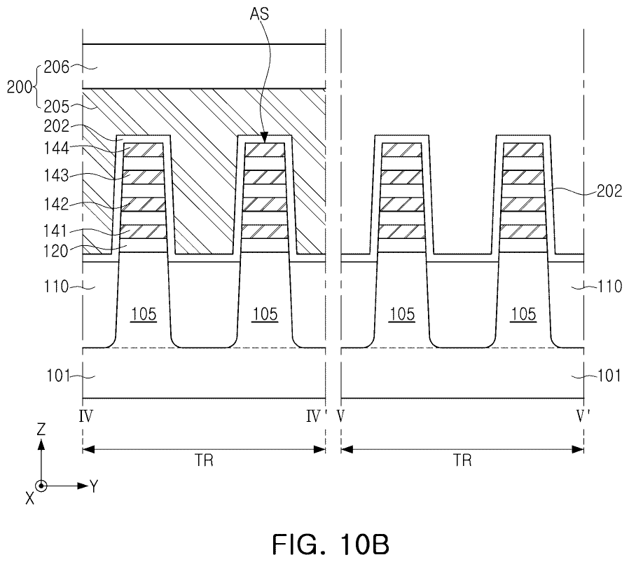

Referring to FIG. 3, in a semiconductor device 100a, protrusions PR of a device isolation layer 110 may extend in the Y-direction from ends of gate structures 160 in a first region R1, unlike the example embodiment of FIG. 1. Accordingly, the protrusions PR may be disposed within lines extending from the gate structures 160. In example embodiments, an extension direction of the protrusions PR may be variously changed in a range of about 0 degrees to about 8 degrees with respect to the Y-direction. In example embodiments, an extension length of the protrusions PR may be changed in various ways depending on a height of a sacrificial gate structure 200 (see FIG. 10A) to form the gate structures 160, a separation distance of the sacrificial gate structure 200, or the like.

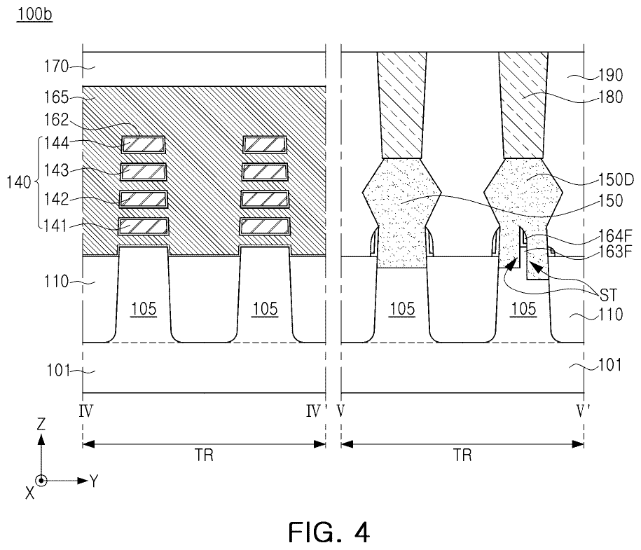

FIG. 4 is a cross-sectional view illustrating a semiconductor device according to example embodiments. FIG. 4 illustrates cross-sections corresponding to FIG. 2B.

Referring to FIG. 4, in a semiconductor device 100b, a shape of an outermost active region 105 closest to a first region R1 may be different from that in the embodiment of FIG. 2B. The outermost active region 105 may have two step portions ST on an upper surface thereof. The outermost active region 105 may have a protruding region due to the step portion ST, in a central region of the upper surface thereof or a region spaced apart from an end thereof. In FIG. 4, the upper surface of the outermost active region 105 may be configured so that a level thereof on the right side of the protruding region may be lower than a level thereof on the left side of the protruding region. However, in a width of the protruding region and a relative position of the upper surface of the outermost active region 105 may be variously changed in various embodiments. First and second fin spacer layers 163F and 164F may be disposed on both side surfaces of a source/drain region 150D and on the upper surface of the protruding region.

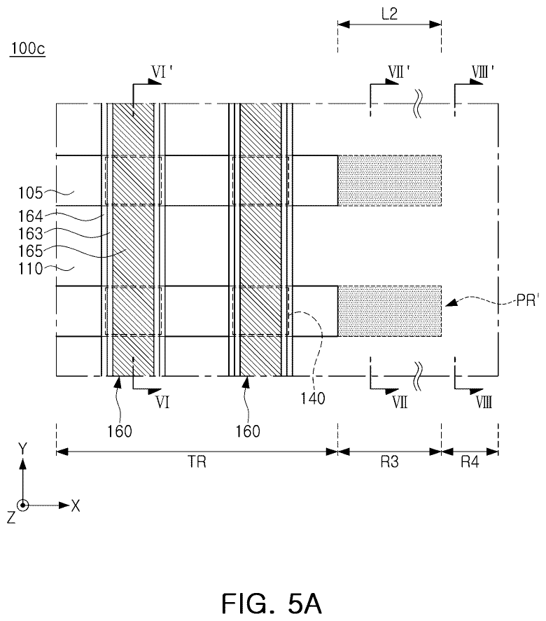

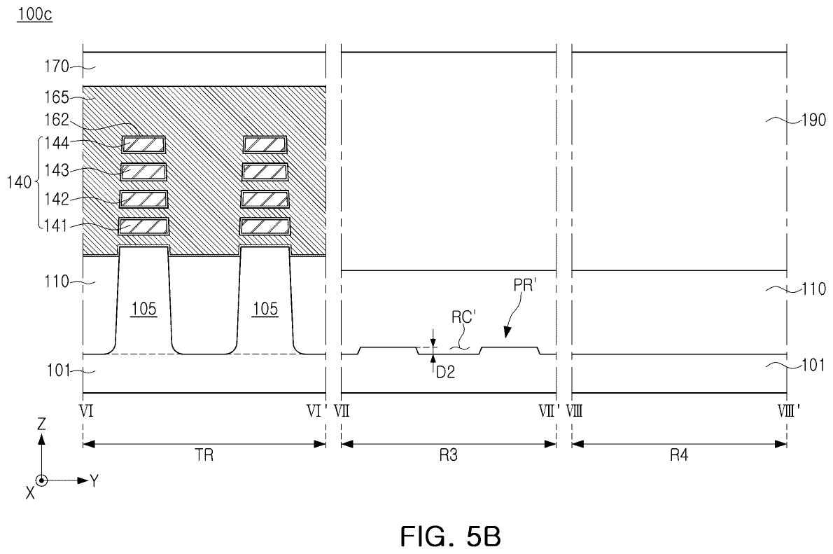

FIGS. 5A and 5B are a plan view and a cross-sectional view illustrating a semiconductor device according to example embodiments. FIG. 5B illustrates cross-sections taken along cutting lines VI-VI′, VII-VII′, and VIII-VIII′ of the semiconductor device of FIG. 5A.

Referring to FIGS. 5A and 5B, in a semiconductor device 100c, an upper surface of a substrate 101 may have protrusions PR′ and recessed portions RC′.

The substrate 101 may include a device region TR, a third region R3, and a fourth region R4. The device region TR is a region in which active regions 105 and gate structures 160 are disposed, and may be, for example, a region in which elements such as transistors are disposed. The third region R3 and the fourth region R4 are regions in which at least the active regions 105 are not disposed, and may be a peripheral region of the device region TR.

In this example embodiment, the third region R3 is a region adjacent to the active regions 105, in an extending direction of the active regions 105, for example, the X-direction, and the fourth region R4 may be a region spaced apart from the device region TR. The third region R3 may be interposed between the fourth region R4 and the device region TR. The third region R3 may be a region up to a second length L2 from one end of the active regions 105, and the fourth region R4 may be a region farther than the second length L2 from one end of the active regions 105. The second length L2 may range from, for example, several tens of nanometers to several thousands of nanometers. The third region R3 illustrated in FIG. 5B corresponds to a region spaced apart by a third distance from one end of the active regions 105, and the fourth region R4 illustrated in FIG. 5B may correspond to a region spaced apart from one end of the active regions 105 by a fourth distance that is longer than the third distance.

In the third region R3, the substrate 101 may have recessed portions RC′ and protrusions PR′ on an upper surface thereof. Accordingly, the substrate 101 may have a curved upper surface and the upper surface may be disposed on at least two levels. The protrusions PR′ may extend from the active regions 105, respectively, and the number of protrusions PR′ may be equal to the number of active regions 105. The protrusions PR′ may be disposed to correspond to each of the active regions 105. Accordingly, a curve of the upper surface of the substrate 101 may have a shape corresponding to the active regions 105. The protrusions PR′ may extend from the ends of the active regions 105 in the X-direction which is an extension direction of the active regions 105. The recessed portions RC′ may be disposed between the protrusions PR′. A recessed depth D2 of the recessed portions RC′ may range, for example, from several nanometers to several tens of nanometers, and may be variously changed in example embodiments.

In the fourth region R4, the substrate 101 may have a substantially flat upper surface without any recessed portions or protrusions. A level of the upper surface of the substrate 101 in the fourth region R4 may be substantially identical to a level of the upper surface of the substrate 101 in the recess portions RC′ of the third region R3. The level of the upper surface of the substrate 101 in the fourth region R4 may be lower than a level of an uppermost surface of the device isolation layer 110 in the third region R3, that is, a level of the protrusions PR′.

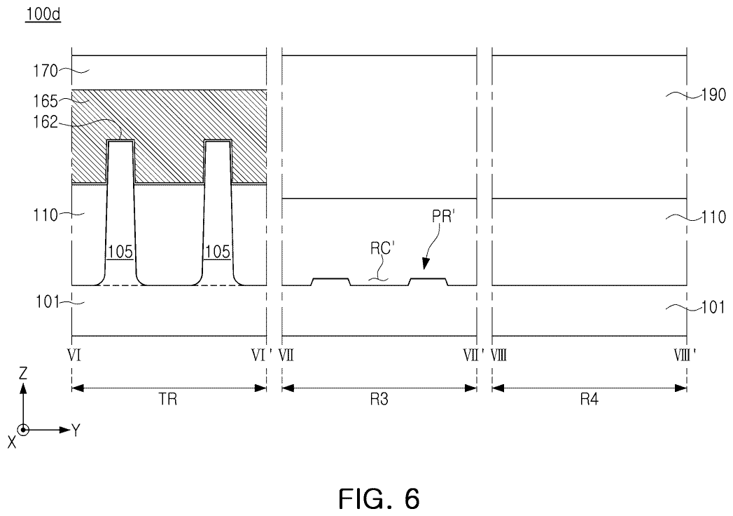

FIG. 6 is a cross-sectional view illustrating a semiconductor device according to example embodiments. FIG. 6 illustrates a region corresponding to FIG. 5B.

Referring to FIG. 6, a semiconductor device 100d may not include channel structures 140, unlike the embodiment of FIG. 5B. The semiconductor device 100d may include FinFETs that do not include a separate channel layer. In the semiconductor device 100d, channel regions of transistors may be limited and disposed to active regions 105 of a fin structure, which is an active structure. Accordingly, separate channel layers may not be interposed in gate electrodes 165. In addition, the descriptions in the example embodiments of FIGS. 5A and 5B may be applied equally to the description of recessed portions RC′ and protrusions PR′ of the substrate 101.

In some example embodiments, the example embodiments described above with reference to FIGS. 1 to 4 may also include FinFETs that do not include a separate channel layer, like this example embodiment.

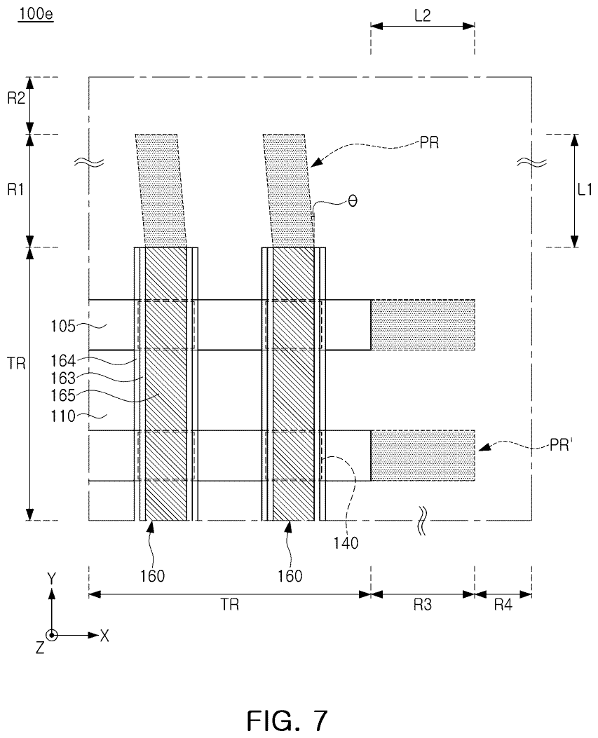

FIG. 7 is a plan view illustrating a semiconductor device according to example embodiments.

Referring to FIG. 7, a semiconductor device 100e may include the protrusions PR of the device isolation layer 110 described above with reference to FIGS. 1 to 2B, and may also include the protrusions PR′ of the substrate 101 described above with reference to FIGS. 5A and 5B. In the semiconductor device 100e, a first region R1 and a second region R2 may have the structure described above with reference to FIGS. 1 to 2B, and a third region R3 and a fourth region R4 may have the structure described above with reference to FIGS. 5A and 5B.

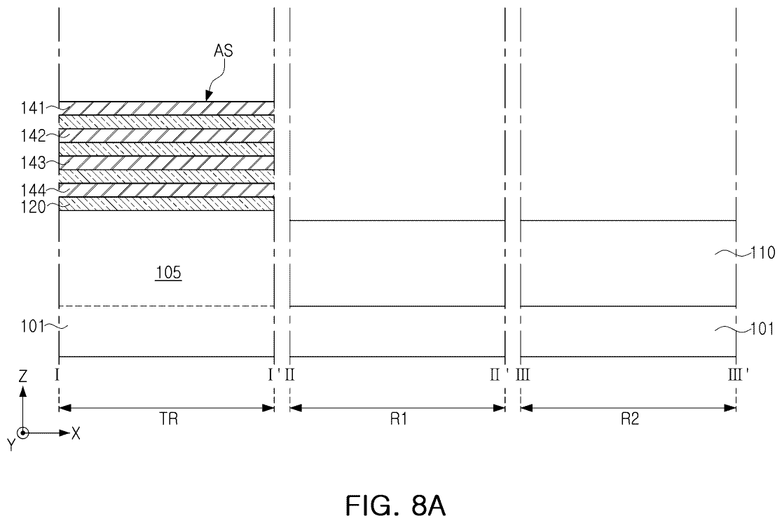

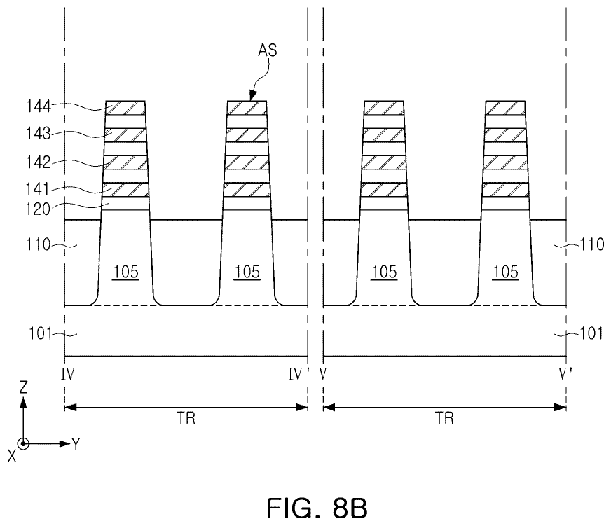

FIGS. 8A to 17B are views illustrating a process sequence to describe a method of manufacturing a semiconductor device according to example embodiments. FIGS. 8A to 17B illustrate an example embodiment of a manufacturing method for manufacturing the semiconductor device of FIGS. 1 to 2B.

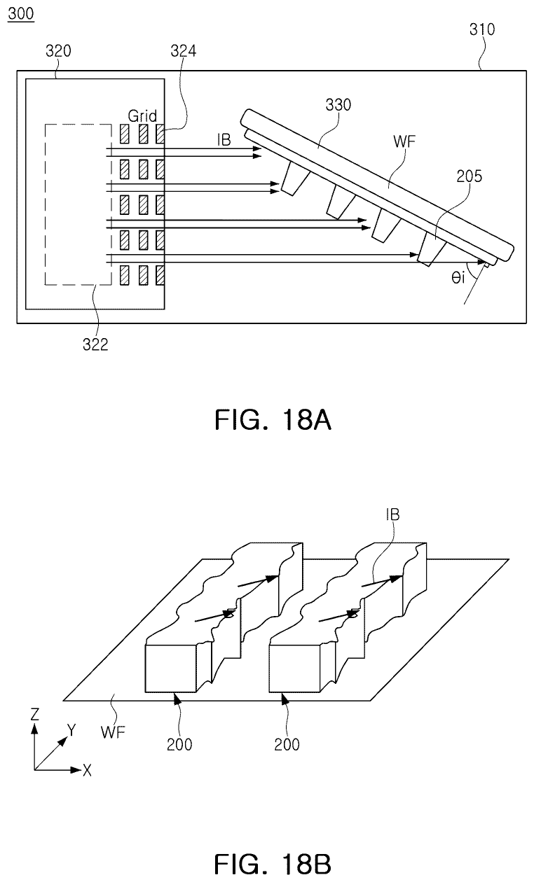

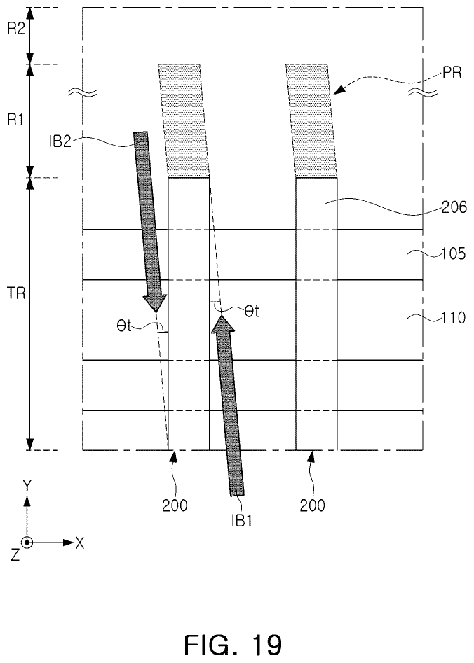

FIGS. 18A, 18B, and 19 are diagrams describing some processes in a method of manufacturing a semiconductor device according to example embodiments.

First, referring to FIGS. 8A and 8B, sacrificial layers 120 and first to fourth channel layers 141, 142, 143 and 144 may be alternately stacked on a substrate 101, and the sacrificial layers 120, the first to fourth channel layers 141, 142, 143 and 144, and the substrate 101 may be partially removed to form active structures AS, and a device isolation layer 110 may be formed.

The sacrificial layers 120 may be layers that are replaced with gate dielectric layers 162 and gate electrodes 165 below a first channel layer 141 through a subsequent process, as illustrated in FIG. 2A. The sacrificial layers 120 may be formed of a material having etch selectivity with respect to the first to fourth channel layers 141, 142, 143 and 144, respectively. The first to fourth channel layers 141, 142, 143 and 144 may include a material different from the sacrificial layers 120. The sacrificial layers 120 and the first to fourth channel layers 141, 142, 143 and 144 may include, for example, a semiconductor material including at least one of silicon (Si), silicon germanium (SiGe), and germanium (Ge), but may include different material, and may or may not include impurities. For example, the sacrificial layers 120 may include silicon germanium (SiGe), and the first to fourth channel layers 141, 142, 143 and 144 may include silicon (Si).

The sacrificial layers 120 and the first to fourth channel layers 141, 142, 143 and 144 may be formed by performing an epitaxial growth process. The number of channel layers alternately stacked with the sacrificial layers 120 may be variously changed in example embodiments.

Each of the active structures AS may include an active region 105 and first to fourth channel layers 141, 142, 143 and 144. The active structures AS may be formed in the form of a line extending in one direction, for example, the X-direction, and may be formed to be spaced apart from adjacent active structures AS in the Y-direction.

In a region in which portions of each of the active region 105, the sacrificial layers 120, and the first to fourth channel layers 141, 142, 143 and 144 are removed, a device isolation layer 110 may be formed by filling an insulating material and partially removing the insulating material so that the active region 105 protrudes. An upper surface of the device isolation layer 110 may be formed to be lower than an upper surface of the active region 105.

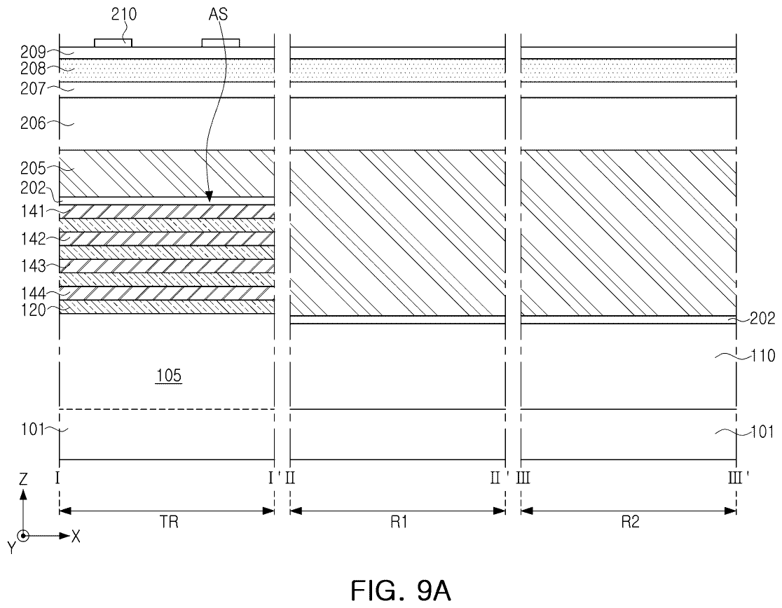

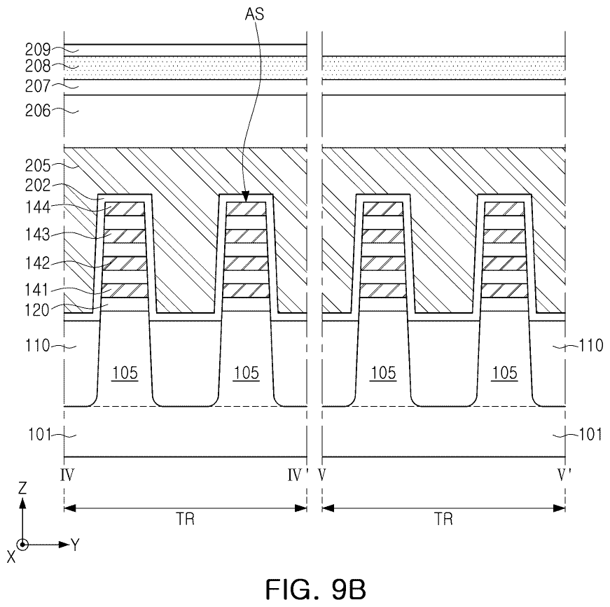

Referring to FIGS. 9A and 9B, a horizontal insulating layer 202, first and second sacrificial gate layers 205 and 206, first to third mask layers 207, 208 and 209, and a photoresist pattern 210 may be formed on the active structures AS.

The horizontal insulating layer 202 may be a layer formed and removed according to a manufacturing process necessity, and may include an insulating material. The first and second sacrificial gate layers 205 and 206 may form a sacrificial gate structure formed in a region in which the gate dielectric layers 162 and the gate electrode 165 are disposed on the channel structure 140, through a subsequent process, as illustrated in FIG. 2A. Each of the first and second sacrificial gate layers 205 and 206 may be a conductive layer and an insulating layer, but is not limited thereto. For example, the first sacrificial gate layer 205 may include polysilicon, and the second sacrificial gate layer 206 may include silicon nitride.

The first to third mask layers 207, 208 and 209 may be mask layers for patterning the first and second sacrificial gate layers 205 and 206. The first to third mask layers 207, 208 and 209 may include different materials, and may include, for example, one of silicon oxide, an amorphous carbon layer (ACL), and silicon oxynitride. However, in example embodiments, the number and a relative thickness of the mask layers may be variously changed.

The photoresist pattern 210 may be formed in a position corresponding to the gate dielectric layers 162 and the gate electrodes 165 of FIGS. 1 to 2B. The photoresist pattern 210 may include, for example, a photoresist material for EUV, and may be formed by patterning by a lithography process using EUV as a light source. For example, the photoresist pattern 210 may include chemically amplified resists.

Referring to FIGS. 10A and 10B, the first to third mask layers 207, 208 and 209 and the first and second sacrificial gate layers 205 and 206 may be patterned using the photoresist pattern 210, thus forming the sacrificial gate structures 200.

First, the first to third mask layers 207, 208 and 209 and the second sacrificial gate layer 106 may be patterned using the photoresist pattern 210 to form upper patterns, and the first sacrificial gate layer 205 may be patterned using the upper patterns. Accordingly, a portion of the first sacrificial gate layer 205 and the second sacrificial gate layer 206 may remain, and sacrificial gate structures 200 may be formed on a portion of the device region TR. In regions in which the photoresist pattern 210 has not been formed, all of the first to third mask layers 207, 208 and 209 and the first and second sacrificial gate layers 205 and 206 may be removed.

The sacrificial gate structures 200 may have a linear shape that intersects the active structures AS and extends in one direction. The sacrificial gate structures 200 may extend in, for example, the Y-direction.

Referring to FIGS. 11A and 11B, a first ion beam IB1 etching process may be performed on the sacrificial gate structures 200. Referring to FIGS. 12A and 12B, a second ion beam IB2 etching process may be performed on the sacrificial gate structures 200.

The first ion beam IB1 etching process and the second ion beam IB2 etching process may be performed by radiating ion beams IB1 and IB2 to an upper surface of the substrate 101 at an ultra-low angle so as to improve LER and LWR of the sacrificial gate structures 200.

Specifically, referring to FIG. 18A, an ion beam etching process may be performed using an ion beam etching device 300. The ion beam etching device 300 may include a process chamber 310, an ion source 320, and a substrate support 330.

The process chamber 310 is a housing and may provide a space in which an ion beam etching process is performed and provide a sealed internal space in which a substrate WF is processed. The ion source 320 may irradiate an ion beam IB toward the substrate WF. The ion source 320 may include a plasma region 322 and grids 324. The ion beam IB may be accelerated by a grid 324 from the plasma region 322 and proceed to the substrate WF.

The substrate support 330 may fix the substrate WF to an upper surface thereof and adjust an angle of the substrate WF. The substrate support 330 may include, for example, an electrostatic chuck. The substrate WF may have sacrificial gate structures 200 formed on an upper surface thereof, and may correspond to an entire structure described above with reference to FIGS. 10A and 10B.

During the ion beam etching process, the ion beam IB may be incident at a desired and/or alternatively predetermined incident angle θi with respect to a direction, perpendicular to the upper surface of the substrate WF. The angle of incidence θi may have a range of about 85 degrees or more and less than about 90 degrees (85 degrees≤θi<90 degrees). The ion beam IB may be incident on the upper surface of the substrate WF at an ultra-low angle of 5 degrees or less.

Referring to FIG. 18B, as the ion beam IB is incident on the upper surface of the substrate WF at an ultra-low angle, a movement distance of the ions may increase and the probability of collision with the sacrificial gate structures 200 may increase. Accordingly, the LER and LWR may be effectively improved. Additionally, since the total amount of ions reaching an upper surface of the entire structure is reduced, a phenomenon in which sputtering occurs on the upper surface of the entire structure to generate by-products, and such by-products are re-deposited on side surfaces of the sacrificial gate structures 200, thereby changing in a width of the sacrificial gate structures 200, may be minimized. As a result of a separate test, when the angle of incidence θi is 60 degrees and 75 degrees, the upper surface of the entire structure, e.g., a bottom surface between the patterns, was recessed, and redeposition occurred on side surfaces of the patterns. However, if the angle of incidence θi is 85 degrees, a recessing phenomenon of the bottom surface and a passivation phenomenon of the side surface did not occur.

Referring to FIG. 19, the first ion beam IB1 may be horizontally tilted and incident by a desired and/or alternatively predetermined inclination angle θt on an X-Y plane with respect to the Y-direction, which is an extending direction of the sacrificial gate structures 200. The inclination angle θt may have a range of −5 degrees≤θt≤+5 degrees. For example, the first ion beam IB1 may be incident at an incident angle θi in the aforementioned range with respect to a direction, perpendicular to the upper surface of the substrate WF, and may be simultaneously tilted and incident by about 5 degrees from a right surface of the sacrificial gate structure 200 as seen from a first end of the sacrificial gate structure 200. The second ion beam IB2 may be incident at an angle of inclination angle (6t)+180 degrees of the first ion beam IB1. For example, the second ion beam IB2 may be incident at an incident angle θi in the aforementioned range with respect to the direction, perpendicular to the upper surface of the substrate WF, and may be simultaneously tilted and incident by about 5 degrees from the right surface of the sacrificial gate structure 200 as seen from a second end of the sacrificial gate structure 200.

Referring again to FIGS. 11A and 11B, the first ion beam IB1 may be incident on right surfaces of the sacrificial gate structures 200. Thereby, the LER of the right surfaces of the sacrificial gate structures 200 may be improved.

In this operation, in the first region R1, recessed portions RC may be formed in a region in which the first ion beam IB1 is irradiated, and since the recessed portions RC are not formed in a region in which the first ion beam IB1 is obscured by the sacrificial gate structures 200, protrusions PR may be formed. Accordingly, the upper surface of the device isolation layer 110 may be disposed on a first level LV1 in an operation of FIG. 10B, and in this operation, in the recessed portions RC, the upper surface of the device isolation layer 110 may be disposed on a second level LV2 that is lower than the first level LV1. The horizontal insulating layer 202 may be removed from the recess portions RC. However, depending on a depth of the recessed portions RC, a thickness of the horizontal insulating layer 202, or the like, the horizontal insulating layer 202 may remain. In the second region R2, as the first ion beam IB1 may be irradiated to an entire region without being obscured, the upper surface of the device isolation layer 110 may be disposed on the second level LV2. A first length L1 (see FIG. 1) of the first region R1 in which the protrusions PR are formed may be calculated from the height of the sacrificial gate structures 200 and the above-described incident angle θi and inclination angle θt in this operation.

As illustrated in FIG. 11B, in a region between the active structures AS outside the sacrificial gate structures 200, the device isolation layer 110 may be obscured by the sacrificial gate structures 200 and may not be recessed.

Referring again to FIGS. 12A and 12B, the second ion beam IB2 may be incident toward left surfaces of the sacrificial gate structures 200, and may be incident from an opposite direction in the Y-direction. Thereby, the LER of the left surfaces of the sacrificial gate structures 200 may be improved.

In this operation, in both the first region R1 and the second region R2, the second ion beam IB2 may be irradiated entirely without obscuring any regions. Accordingly, in the first region R1, the upper surface of the device isolation layer 110 may be disposed on third and fourth levels LV3 and LV4, which are lower than the first and second levels LV1 and LV2, respectively, and in the second region R2, the upper surface of the device isolation layer 110 may be disposed on the fourth level LV4. In some example embodiments, the shapes of the protrusions PR and recessed portions RC may be somewhat relaxed by this operation. In some example embodiments, after the second ion beam IB2 etching process is performed first, the first ion beam IB1 etching process may be performed.

As illustrated in FIG. 12B, outside the sacrificial gate structures 200, an outermost active structure AS adjacent to ends of the sacrificial gate structures 200 may be partially removed, together with the horizontal insulating layer 202, by the second ion beam IB2. Accordingly, an outer region of the outermost active structure AS, a right region of FIG. 12B, may be partially removed to form a removal region SR, and a step portion may be formed in the outermost active structure AS. In example embodiments, the shape and size of the removal region SR may be variously changed. For example, the example embodiment of FIG. 4 may be manufactured with the removal region SR formed at a relatively large width in this operation.

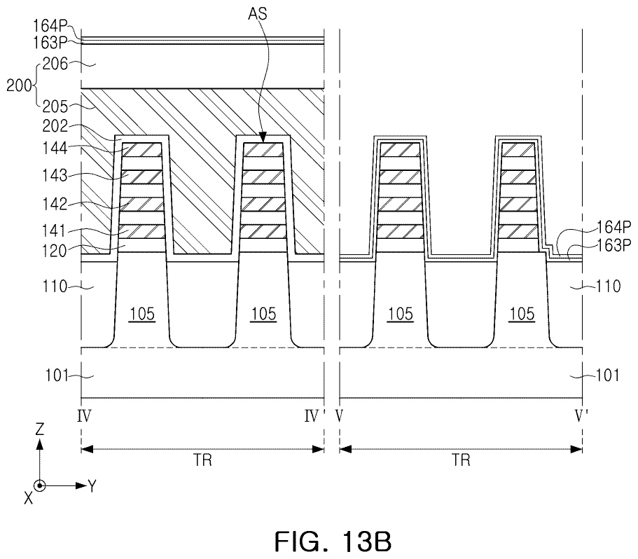

Referring to FIGS. 13A and 13B, the horizontal insulating layer 202 may be partially removed and first and second preliminary gate spacer layers 163p and 164p may be formed.

The horizontal insulating layer 202 may be removed from a region exposed from the sacrificial gate structures 200, for example, using a wet etching process. The first and second preliminary gate spacer layers 163p and 164p may be sequentially formed on the sacrificial gate structures 200 and the device isolation layer 110. The first and second preliminary gate spacer layers 163p and 164p may be formed of a low dielectric constant material, and may include, for example, at least one of SiO, SiN, SiCN, SiOC, SiON, and SiOCN.

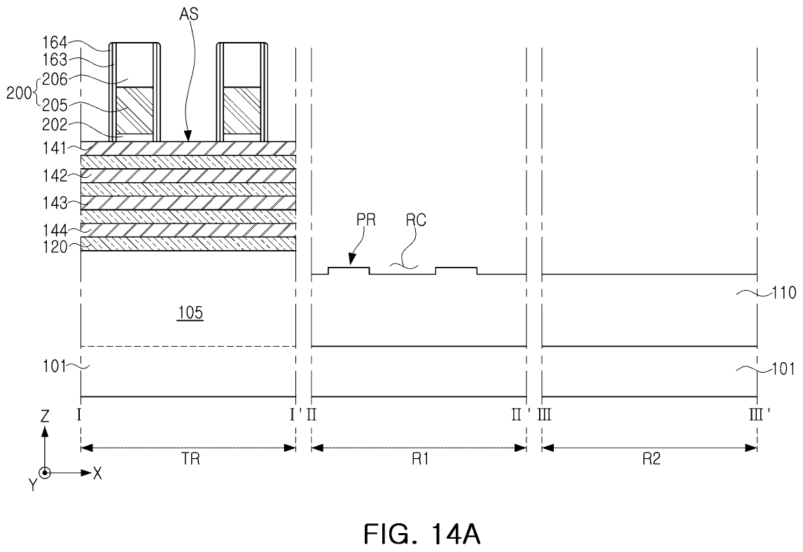

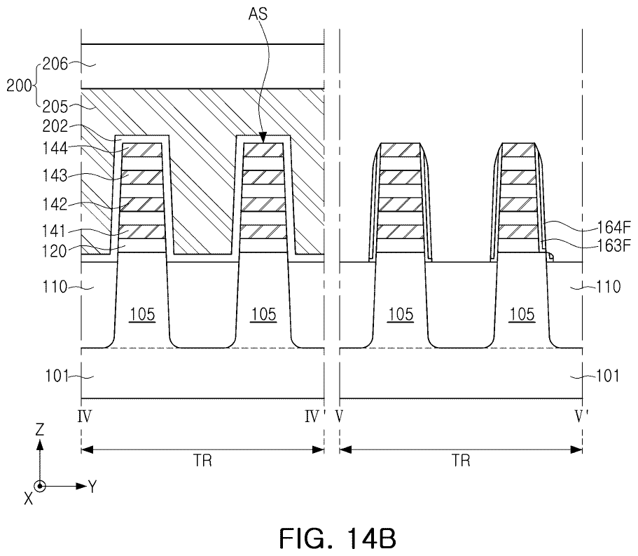

Referring to FIGS. 14A and 14B, first and second gate spacer layers 163 and 164 may be formed.

The first and second preliminary gate spacer layers 163p and 164p may be etched-back, for example, to form first and second gate spacer layers 163 and 164. The first and second gate spacer layers 163 and 164 may be formed on side surfaces of the sacrificial gate structures 200 and side surfaces of the active structures AS. Both the first and second preliminary gate spacer layers 163p and 164p may be removed from the first region R1 and the second region R2. As illustrated in FIG. 14B, in an outermost active region AS, the first and second fin spacer layers 163F and 164F may be formed in two stages by the removal region SR on a right surface thereof.

Referring to FIGS. 15A and 15B, active recess regions SRC may be formed by partially removing the active structures AS exposed from the sacrificial gate structures 200.

By using the sacrificial gate structures 200 and the first and second gate spacer layers 163 and 164 as masks, a portion of exposed sacrificial layers 120 and a portion of the first to fourth channel layers 141, 142, 143 and 144 may be removed to form active recess regions SRC. Accordingly, the first to fourth channel layers 141, 142, 143 and 144 may form channel structures 140 having a limited length in the X-direction.

As illustrated in FIG. 15B, an active recess region SRC having a relatively narrow width in the Y-direction may be formed in the outermost active region AS. In this operation, the first and second fin spacer layers 163F and 164F may be partially removed so that a height thereof may be lowered, and a final height of the first and second fin spacer layers 163F and 164F may be variously changed in example embodiments.

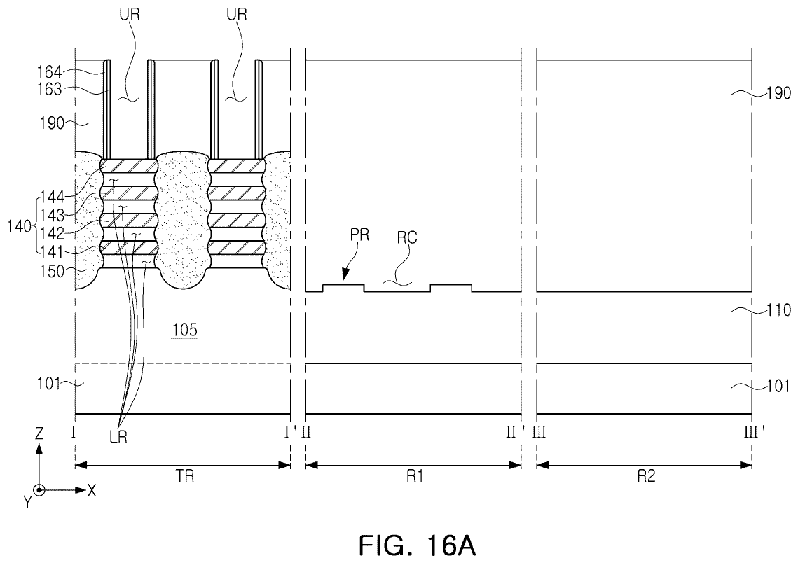

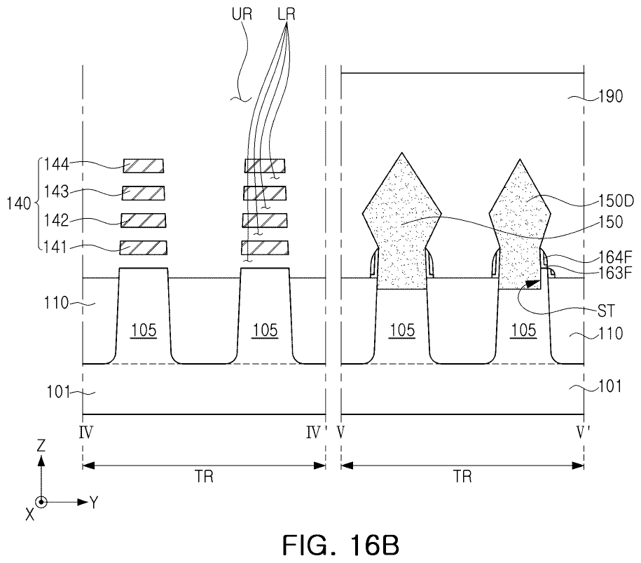

Referring to FIGS. 16A and 16B, source/drain regions 150 may be formed in the active recess regions SRC, an interlayer insulating layer 190 may be formed, and the sacrificial gate structures 200 and the sacrificial layers 120 may be removed.

The source/drain regions 150 may be formed in the active recess regions SRC, and may be formed by growing from side surfaces of the active regions 105 and the channel structures 140 in, for example, a selective epitaxial process. The source/drain regions 150 may include impurities by in-situ doping, and may include a plurality of layers having different doping elements and/or doping concentrations. As illustrated in FIG. 16B, a dummy source/drain region 150D having a relatively narrow width in the Y-direction may be formed on the outermost active region AS. The source/drain regions 150 may be referred to as source/drain structures.

The interlayer insulating layer 190 may be formed to fill a space between the sacrificial gate structures 200. The interlayer insulating layer 190 may be formed to expose the sacrificial gate structures 200 through a planarization process.

The sacrificial gate structures 200 and the sacrificial layers 120 may be selectively removed with respect to the first and second gate spacer layers 163 and 164 and the channel structures 140. First, the sacrificial gate structures 200 may be removed to form upper gap regions UR, and then, the sacrificial layers 120 exposed through the upper gap regions UR may be removed to form lower gap regions LR. For example, when the sacrificial layers 120 include silicon germanium (SiGe) and the channel structures 140 include silicon (Si), the sacrificial layers 120 may be selectively removed from the channel structures 140 by performing a wet etching process.

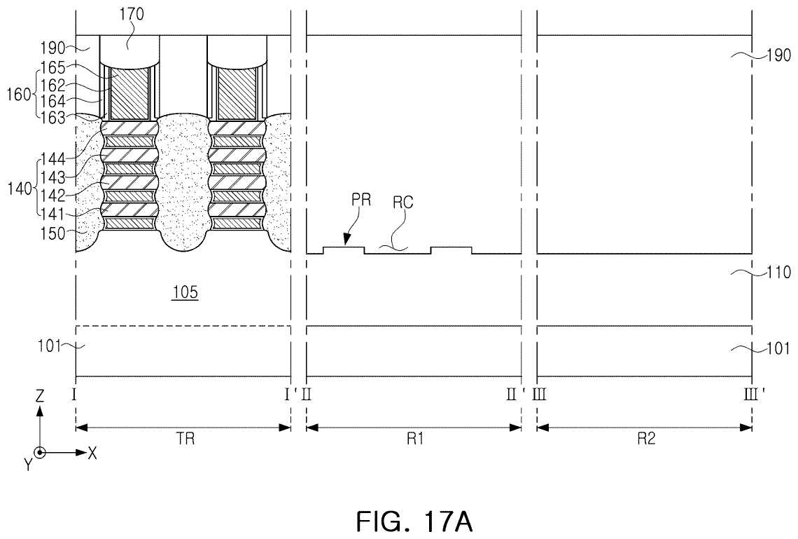

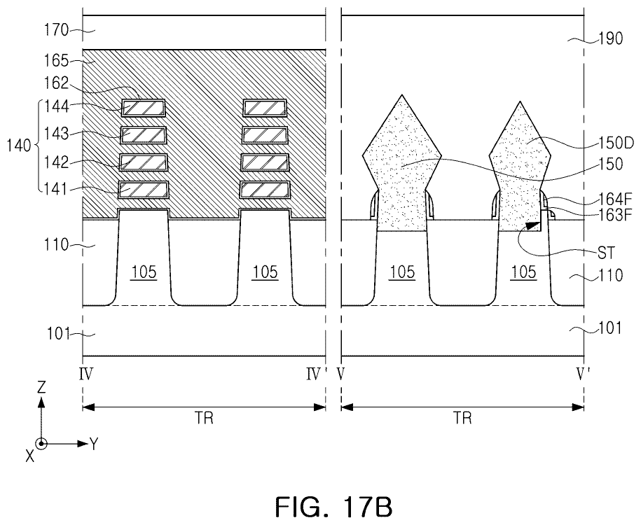

Referring to FIGS. 17A and 17B, gate structures 160 and gate capping layers 170 may be formed.

The gate structures 160 may be formed to fill the upper gap regions UR and the lower gap regions LR. The gate dielectric layers 162 may be formed to conformally cover inner surfaces of the upper gap regions UR and the lower gap regions LR. The gate electrodes 165 may be formed to completely fill the upper gap regions UR and the lower gap regions LR, and may be then removed by a desired and/or alternatively predetermined depth from the top in the upper gap regions UR together with the gate dielectric layers 162 and the first and second gate spacer layers 163 and 164. Accordingly, gate structures 160 including each of the gate dielectric layers 162, the gate electrode 165 and the first and second gate spacer layers 163 and 164 may be formed.

The gate capping layers 170 may be formed by depositing an insulating material to fill regions from which the gate electrode 165, the gate dielectric layers 162, and the first and second gate spacer layers 163 and 164 are removed, and performing a planarization process. A relative thickness of the gate capping layers 170 and a shape of the lower surfaces may be variously changed in example embodiments.

Next, referring to FIG. 2 together, the contact plugs 180 may be formed.

Contact holes exposing the source/drain regions 150 may be formed by patterning the interlayer insulating layer 190. Next, contact plugs 180 may be formed by filling the contact holes with a conductive material.

Specifically, after depositing a material forming a barrier layer in the contact holes above, a metal-semiconductor compound layer such as a silicide layer may be formed in a lower end thereof by performing a silicide process. Next, a conductive material may be deposited to fill the contact holes to form the contact plugs 180. Accordingly, the semiconductor device 100 of FIGS. 1 to 2B may be manufactured.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a substrate including active regions extending in a first direction;
a device isolation layer on the substrate and defining the active regions;
gate structures on the substrate, the gate structures intersecting the active regions and extending in a second direction;
a plurality of channel layers on the active regions and surrounded by the gate structures, the plurality of channel layers being spaced apart from each other in a third direction, the third direction perpendicular to an upper surface of the substrate; and
source/drain regions in recessed regions of the active regions on both sides of the gate structures, the source/drain regions being connected to the plurality of channel layers, wherein
a first region of the substrate is spaced apart from first ends of the gate structures in the second direction by a first length in the second direction,
a second region of the substrate is spaced apart from the first ends of the gate structures by a second length in the second direction,
the second length is longer than the first length,
an upper surface of the device isolation layer on the first region of the substrate has recessed portions, and
the device isolation layer on the second region of the substrate has a flat upper surface.

2. The semiconductor device of claim 1, wherein
the upper surface of the device isolation layer on the first region has protrusions between the recessed portions, and
a number of the protrusions is identical to a number of gate structures.

3. The semiconductor device of claim 2, wherein
the protrusions extend from the first ends of the gate structures.

4. The semiconductor device of claim 3, wherein the protrusions extend from the first ends of the gate structures in a direction inclined with respect to the second direction.

5. The semiconductor device of claim 1, wherein
the upper surface of the device isolation layer in the recessed portions on the first region is a same level as the upper surface of the device isolation layer on the second region.

6. The semiconductor device of claim 1, wherein a depth of the recessed portions ranges from 5 nm to 10 nm.

7. The semiconductor device of claim 1, wherein
a first active region among the active regions is closest to the first ends of the gate structures,
an upper surface of the first active region has a step portion between the gate structures.

8. The semiconductor device of claim 7, wherein
the upper surface of the first active region comprises an end region and an inner region sequentially disposed in the second direction from the first ends of the gate structures,
the upper surface of the first active region is a second level in the end region and a third level in the inner region, and
the third level is lower than the second level.

9. The semiconductor device of claim 7, wherein
the first active region has a protruding region protruding upwardly by the step portion, and
the protruding region of the first active region is spaced apart from an end of the first active region.

10. The semiconductor device of claim 1, wherein
a third region of the substrate is spaced apart from second ends of the active regions in the first direction by a third length in the first direction,
a fourth region of the substrate is spaced apart from the second ends of the active region by a fourth length in the first direction,
the fourth length is longer than the third length, and
the substrate has recessed portions in an upper surface thereof in the third region, and the substrate has a flat upper surface in the fourth region.

11. The semiconductor device of claim 10, wherein
the upper surface of the substrate in the third region has protrusions between the recessed portions, and
a number of the protrusions in the upper surface of the substrate is identical to a number of the active regions.

12. The semiconductor device of claim 11, wherein the protrusions extend in the first direction from the second ends of the active regions.

13. A semiconductor device, comprising:
a substrate including an active region extending in a first direction;
a device isolation layer defining the active region on the substrate;
a gate structure on the substrate, the gate structure extending in a second direction and intersecting the active region; and
a source/drain region on at least one side of the gate structure, wherein
a first region of the substrate and a second region of the substrate are sequentially disposed in the second direction from a first end of the gate structure in the second direction, and
an upper surface of the device isolation layer on the first region has a protrusion corresponding to the gate structure, and
the device isolation layer on the second region has a flat upper surface.

14. The semiconductor device of claim 13, wherein a level of the protrusion of the device isolation layer on the first region is higher than a level of the upper surface of the device isolation layer on the second region.

15. The semiconductor device of claim 13, wherein a length of the first region is 800 nm to 2000 nm in the second direction from the first end of the gate structure.

16. The semiconductor device of claim 13, wherein
a third region of the substrate and a fourth region of the substrate are sequentially disposed in the first direction from a second end of the active region in the first direction, and
a protrusion in an upper surface of the substrate on the third region corresponds to the active region, and
an upper surface of the substrate on the fourth region is flat.

17. A semiconductor device, comprising:
a substrate including active regions extending in a first direction;
a device isolation layer on the substrate and defining the active regions;
gate structures on the substrate, the gate structures intersecting the active regions and extending in a second direction;
a plurality of channel layers on the active regions and surrounded by the gate structure, the plurality of channel layer being spaced apart from each other in a third direction, the third direction perpendicular to an upper surface of the substrate; and
source/drain regions in recessed regions of the active regions at both sides of the gate structures, and the source/drain regions being connected to the plurality of channel layers, wherein
among the active regions, an upper surface of an active region closest to ends of the gate structures in the second direction has a step portion between the gate structures.

18. The semiconductor device of claim 17, wherein
a first region of the substrate is adjacent to the ends of the gate structures in the second direction, and
a second region of the substrate is spaced apart from the ends of the gate structures in the second direction, and
an upper surface of the device isolation layer on the first region of the substrate has protrusions corresponding to the gate structures and recessed portions between the protrusions.

19. The semiconductor device of claim 18, wherein
the protrusions in the upper surface of the device isolation layer on the first region of the substrate are on a straight line with the gate structures in the second direction, or
the protrusions in the upper surface of the device isolation layer on the first region of the substrate are shifted from the straight line in the first direction.

20. The semiconductor device of claim 18, wherein an upper surface of the device isolation layer on the second region is flat.
